(19) United States
(12) Patent Application Publication
(10) Pub. No.: US 2026/0363139 A1
(43) Pub. Date: Nov. 12, 2026

(54) SEMICONDUCTOR CAVITY PACKAGE WITH CHICANE-SHAPED AIR VENT, AND MANUFACTURING METHOD

(71) Applicant: STMICROELECTRONICS INTERNATIONAL N.V., Geneva (CH)

(72) Inventors: Younes BOUTALEB, Grenoble (FR); Lorenzo CERVELLI, Melzo (IT)

(21) Appl. No.: 19/655,121

(22) Filed: Apr. 22, 2026

(30) Foreign Application Priority Data
May 6, 2025 (FR) 2504785

(51) Int. Cl. H10W 76/12; H10F 39/00; H10W 76/01

(52) U.S. Cl. CPC H10W 76/167; H10F 39/804; H10W 76/01

(57) ABSTRACT

A semiconductor cavity package is provided. An example semiconductor cavity package includes a casing made of at least two casing parts assembled to define a cavity and includes a chip on a first casing part in the cavity. One casing part has a chicane-like air vent to couple the cavity with an outside. The casing part is a multilayer part obtained by assembling layers having respective channels that form together, once assembled, the chicane-shaped air vent. An image sensor includes such cavity package where the air vent is located in a surrounding portion of the glass cover of the package. A ceramic package includes such an air vent located in its bottom frame, the outer surface of which is equipped with pads for a circuit board connection. A sealing element surrounding an outlet of the air vent seals the latter after connection to the circuit board.

### CROSS REFERENCE TO RELATED APPLICATIONS

This application claims the priority benefit of French Patent Application Number 2504785, filed on May 6, 2025, entitled “BOITIER SEMICONDUCTEUR A CAVITÉ AVEC UNE PRISE D’AIR EN FORME DE CHICANE, ET PROCÉDÉ DE FABRICATION”, which is hereby incorporated by reference to the maximum extent allowable by law.

### TECHNICAL FIELD

The present disclosure relates to electronic devices and more particularly semiconductor packages and methods of manufacturing the same.

### BACKGROUND

In electronic devices with chips or integrated circuits (ICs), the ICs are typically mounted onto circuit boards. In order to electrically couple connections between the circuit board and the IC, the IC is typically “packaged”. The IC packaging usually provides a small encasement for physically protecting the IC and provides contact pads for coupling to the circuit board. In some applications, the packaged IC may be coupled to the circuit board via pads or solder bumps. Common materials of the package include plastic, metal and ceramic.

A typical IC package is a wafer-level chip scale package (WLCSP), which is an IC package on the wafer before it is diced.

Cavity packages are packages containing a cavity to accommodate the chip or IC. A traditional cavity package includes a bottom frame (or substrate) on which the chip or IC can be mounted or formed, a ringframe (or “holder” or “spacer”) and a lid or cover disposed on the top part of the ringframe. The bottom frame, ringframe and lid form a casing defining the cavity (i.e., an inner volume or space).

An exemplary cavity package includes an image sensor package, wherein the IC is an image sensor chip and the lid is a transparent (e.g., glass) cover arranged above the image sensor chip, spaced apart from it and facing it.

The lid may be hermetically combined with the ringframe. However, this raises some issues. For example, inner overpressure may appear when the package is heated (e.g., to polymerize the glue to adhere the lid to the ringframe when manufacturing the package), which may result in a partial or full detachment of the lid at the weak glue points. Also, contamination, such as micro-droplets, may appear on the inner surface of the transparent cover when the glue used to fix the package degases, which may lead to a deficient image sensor.

A vent hole performed in the lid can couple the cavity with the outside, to evacuate overpressure. However, due to the top position of the hole, risks exist that foreign material, such as dust, gets into the cavity.

Vent holes may be practiced on the ringframe, as disclosed for example in US2014/264699. A sophisticated V-shaped vent hole through the ringframe includes a first stopper freely disposed in the hole and a second stopper adhesively disposed on the outer surface of the ringframe. The first stopper moves to the second stopper to exhaust high inner pressured air to the outside, whereas it closes the hole to seal the cavity in case of low inner pressure.

### BRIEF SUMMARY

More simple vents for cavity packages are needed to ensure proper high pressured air exhaustion while protecting the package from inner contamination by foreign material.

In this respect, embodiments of the disclosure regard a semiconductor package comprising: a casing defining a cavity and having a chicane-shaped air vent to couple the cavity with an outside (i.e., passing through a casing wall), and a chip in the cavity, wherein the chicane-shaped air vent is formed by an assembly of channels performed in respective layers of a multilayer casing part.

Embodiments also concern a method of manufacturing a semiconductor package, the method comprising:
providing a chip on a first casing part,
assembling the first casing part with a second casing part to obtain a casing defining a cavity in which the chip is provided,
wherein at least one of the first and second casing parts is obtained by assembling multiple layers having respective channels that form together a chicane-shaped air vent coupling the cavity with an outside.

Elementary channels can therefore be formed in each layer in a simple way, to obtain, through multiple layer assembly, a complex chicane-shaped air vent that reduces risks of contamination by foreign material, while ensuring air exhaustion.

Optional aspects of the disclosure are defined below with reference to methods, while they can be transposed into device features.

In some embodiments, the channels are straight portions (e.g., holes, openings, through-opening slots, grooves) performed in the respective layers. Elementary channels that are simple to be formed in the layers are therefore used. From process perspective, assembling multiple layers includes performing straight channels in the multiple layers.

In some embodiments, a cross-section of the chicane-shaped air vent includes two or more straight portions disposed at right angle one with the other. Each straight portion is thus preferably either parallel or perpendicular to the (inner, outer) surfaces of the multilayer casing part.

In some embodiments, a cross-section of the chicane-shaped air vent includes one chicane only. A minimum of two layers can be used, simplifying the manufacturing process. Alternatively, a cross-section of the chicane-shaped air vent includes two chicanes only. A “buried channel” in the intermediary layer thus introduces a shift between the inlet and outlet of the air vent, which is beneficial to contamination protection. Such configuration is needed when the inlet and outlet of the air vent are disposed at opposite faces of the same casing part. Of course, a higher number of chicanes (e.g., with right angles) can be used to have more complex chicane shapes.

In some embodiments, the chicane-shaped air vent is located in a cover of the casing, facing an upper surface of the chip. It means the air vent is performed on the second casing part (cover) and not on the first casing part on which the chip is formed or mounted. This configuration is particularly advantageous to image sensors where the cover is a transparent or glass cover facing the sensing face of the image sensor chip.

In particular embodiments, the chicane-shaped air vent is located in a surrounding portion of the cover, not directly facing the top surface of the chip. It means the air vent is laterally shifted from the active part of the cover, typically for light propagation to or from the chip. This reduces disfunction of the chip used as sensor or light emitter.

In some embodiments, the chicane-shaped air vent is performed in a bottom frame of the casing, an outer surface of the bottom frame including metal pads to connect the semiconductor package to a circuit board. Providing the air vent in the bottom frame advantageously reduces risks of contamination since the air vent is not subject to dust contamination by gravity.

In particular embodiments, an outlet of the chicane-shaped air vent in the outer surface of the bottom frame is surrounded by one or more stoppers or a sealing element.

Stoppers around the outlet may reduce air flow within the chicane-shaped air vent.

The sealing element on the bottom outer surface advantageously allows high pressured air to be exhausted when manufacturing the semiconductor package (e.g., when heating the glue to close the casing) not yet mounted on a circuit board, while avoiding any internal contamination as soon as the semiconductor package is mounted on the circuit board, due to the sealing of the air vent by the surrounding element.

In particular embodiments, the bottom frame is a ceramic frame and the one or more stoppers or sealing element include a metalized land. Indeed, some applications of the bottom-frame air vent are directed to ceramic packages.

In some embodiments, an outlet of the chicane-shaped air vent opens in a side surface of the casing.

In alternative embodiments, an outlet of the chicane-shaped air vent opens in a top surface of the casing.

In other alternative embodiments, an outlet of the chicane-shaped air vent opens in a bottom surface of the casing used to mount the semiconductor package on a circuit board.

In some embodiments, the chicane-shaped air vent includes two or more outlets to the outside. The two or more outlets may open in the same outer surface of the casing or in different outer surfaces (e.g., top and side surfaces). Similarly, multiple inlets may be provided in the chicane-shaped air vent.

Although a single chicane-shaped air vent is described above, multiple chicane-shaped air vents may be provided in the same semiconductor package, either in the same casing part or in different casing parts (e.g., one in the cover and the other in the bottom frame of the casing).

### BRIEF DESCRIPTION OF THE DRAWINGS

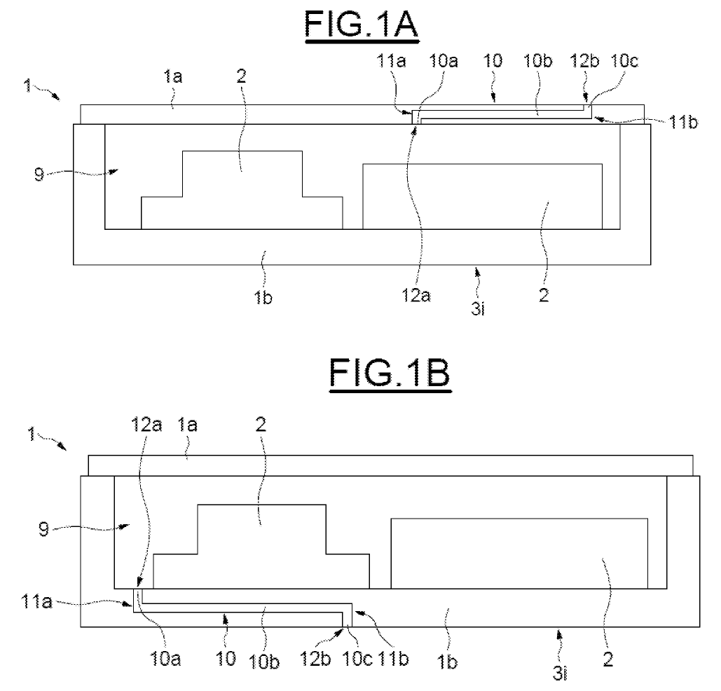

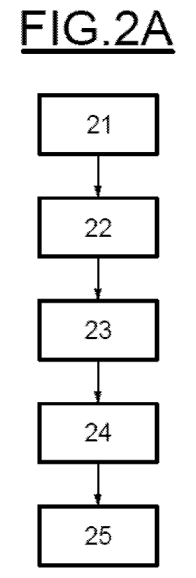

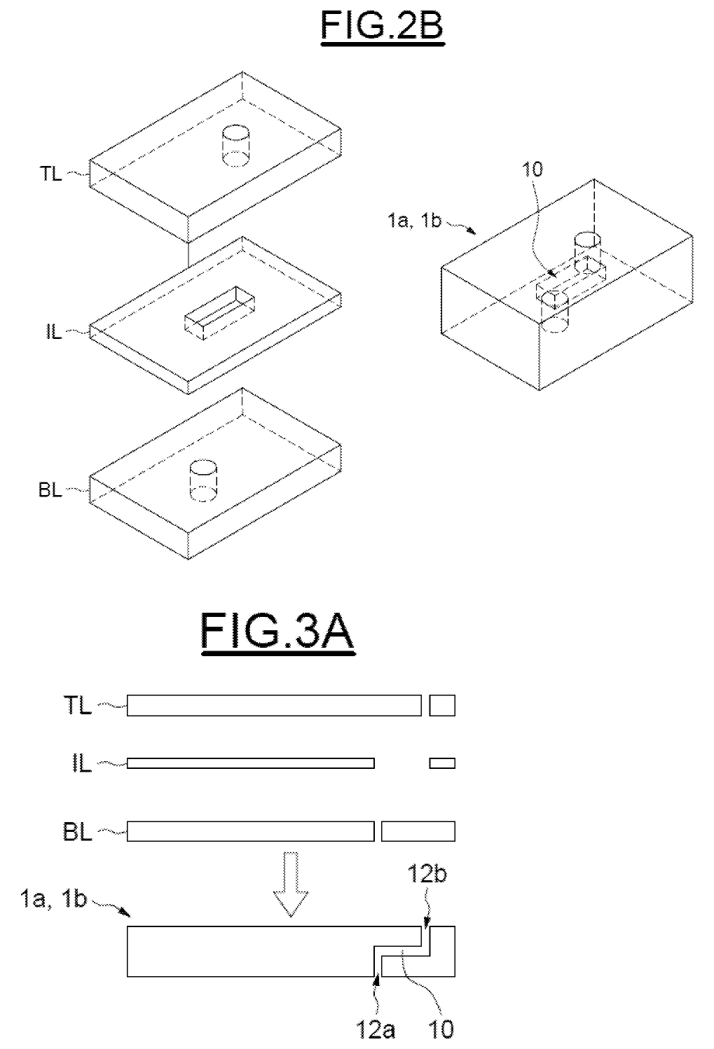

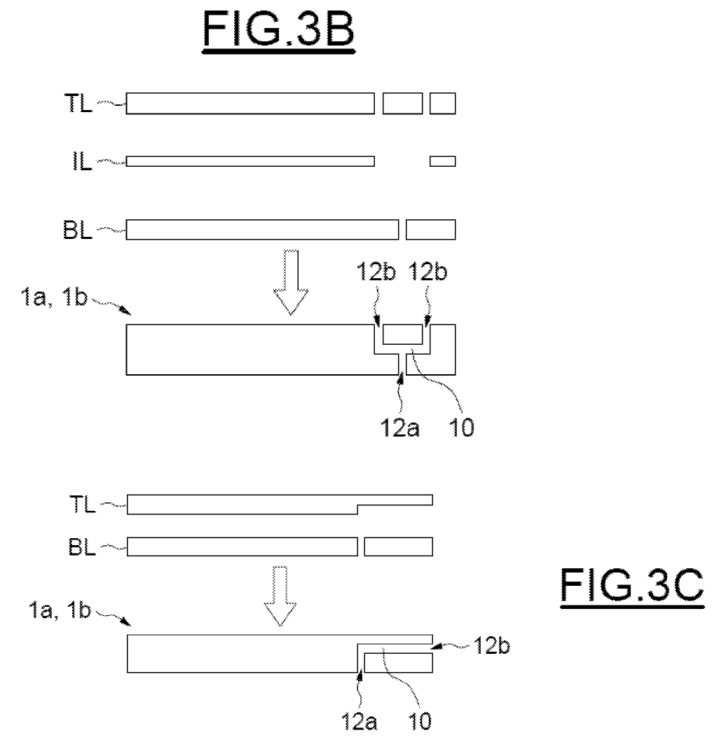

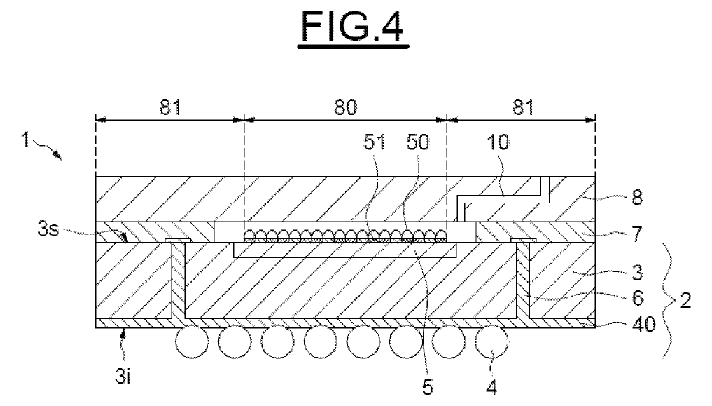

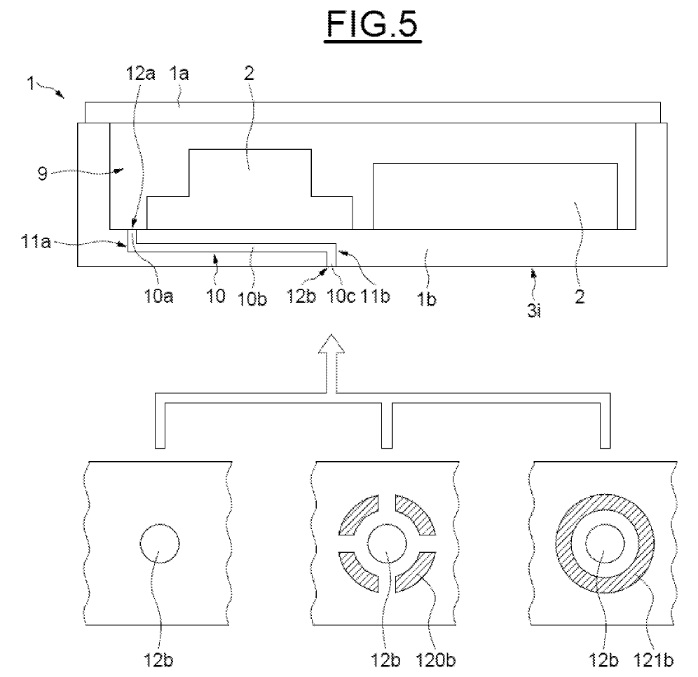

Other advantages and characteristics of the present disclosure will become apparent from the detailed description of the non-limiting embodiment and implementations and from the appended drawings in which: FIG. 1A; FIG. 1B; FIG. 2A; FIG. 2B; FIG. 3A; FIG. 3B; FIG. 3C; FIG. 4; and FIG. 5 schematically illustrate embodiments and implementations of the present disclosure.

### DETAILED DESCRIPTION

Exemplary embodiments of the present disclosure will now be described more fully hereinafter with reference to the accompanying drawings, in which exemplary embodiments of the present disclosure are shown. It should be noted, however, that exemplary embodiments of the present disclosure are not limited to exemplary embodiments set forth herein, and may be implemented in various forms. In the drawings, embodiments of the present disclosure are not limited to the specific examples provided herein and may be exaggerated for clarity.

The terminology used herein is for the purpose of describing particular embodiments only and is not intended to limit the present disclosure. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

When reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the Figures or to an electronic circuit in a normal position of use. Unless otherwise specified, the expressions “about”, “approximately”, “substantially”, and “of the order of” mean to within 10%, preferably to within 5%.

The same reference numerals or the same reference designators denote the same elements throughout the specification.

A semiconductor cavity package of the present disclosure comprises a casing made of at least two casing parts assembled together to define a cavity and comprises a chip provided on a first casing part in the cavity. One of the casing parts has a chicane-like air vent passing through the casing part to couple the cavity with an outside. The casing part is a multilayer part obtained by assembling multiple layers having respective channels that form together, once assembled, the chicane-shaped air vent. An image sensor comprises such cavity package where the air vent is located in a surrounding portion of the glass cover of the package. A ceramic package includes such an air vent located in its bottom frame, the outer surface of which is equipped with pads for connection to a circuit board. A sealing element surrounding an outlet of the air vent ensures sealing the latter after connection to the circuit board.

FIG. 1A illustrates first embodiments of a semiconductor cavity package 1 where a chicane-shaped air vent 10 is located in a cover of the casing. FIG. 1B illustrates second embodiments of a semiconductor cavity package 1 where a chicane-shaped air vent 10 is located in a bottom frame of the casing.

The semiconductor cavity package 1 is formed by a first casing part 1a, namely a lid or cover, and a second casing part 1b, namely the bottom frame. In the example, the bottom frame 1b is a tubular element with a rectangular horizontal cross-section and U-shape vertical cross-section. The bottom frame 1b may be formed by an assembly of a back frame and a ringframe.

One or more chips 2 are formed or mounted on the bottom frame, in particular in the recess of the U-shape bottom frame. The cover 1a is adhered, e.g., using glue, to the bottom frame 1b in order to form a casing with a cavity 9 in which the one or more chips are located.

Usually, the bottom frame 1b of the casing is used for connection to a printed circuit board PCB (not shown). An outer surface 3i of the bottom frame 1b usually includes pads (not shown) to connect the semiconductor package to the PCB.

The cover 1a and/or the bottom frame 1b are obtained by an assembly of multiple layers, using known techniques such as fusion bonding. The chicane-shaped air vent 10 shown in the Figures results from an assembly of elementary channels performed in the respective layers of the multilayer casing part (cover or bottom frame).

Due to the multilayer structure, the chicane-shaped air vent 10 is made of successive straight vent portions disposed at right angle one with the next one. Each straight vent portion, in the cross-section view, is either parallel or perpendicular to the (inner, outer) surfaces of the multilayer casing part.

Each straight vent portion may correspond to a single layer of the multilayer structure, or may correspond to multiple layers that are stacked on top of each other with their elementary channels being aligned.

In the exemplary packages of the Figures, the chicane-shaped air vent 10 includes three straight vent portions 10a, 10b, 10c that define two chicanes 11a and 11b between them. The right angle (about 90° given manufacturing tolerance or uncertainty) between two successive vent portions 10a, 10b, 10c is defined between the main axes of the vent portions, which main axes corresponds to the air circulation direction in the vent portions.

One end 12a of the chicane-shaped air vent 10 opens in the cavity 9. As the chicane-shaped air vent 10 intends to exhaust high pressured air in the cavity, end 12a may operate as an inlet. The other end 12b of the chicane-shaped air vent 10 opens in an outer surface of the casing, namely the outer surface of cover 1a in FIG. 1A and the outer surface 3i of the bottom frame in FIG. 1B. As the chicane-shaped air vent 10 intends to exhaust high pressured air in the cavity, end 12b may operate as an outlet.

Of course, as explained below, other chicane shapes can be formed through appropriate assemblies of elementary channels in multiple layers.

FIG. 2A illustrates, using a flowchart, a manufacturing process 20 of a semiconductor cavity package 1 having a chicane-shaped air vent 10 according to embodiments, whereas FIG. 2B schematically illustrates a manufacturing process of a multilayered casing part 1a, 1b having a chicane-shaped air vent 10 according to embodiments.

At step 21, multiple layers to form one casing part (e.g., cover 1a or bottom frame 1b) are obtained. In some embodiments, the layers are glass layers, for instance to obtain a glass cover. In other embodiments, the layers are ceramic layers to obtain a ceramic casing 1b. Other materials can be used instead.

At step 22, the multiple layers are machined to perform elementary channels in each of them. Position and size of the channels are defined beforehand (e.g., through computer-assisted designing) so that the stacking of the layers leads to a predefined chicane shape of the assembled channels.

One or more elementary channels can be through-opening channels, i.e., channels that pass through the layer. Such through-opening channels include holes, openings (e.g., circular openings), through-opening slots, and so on.

One or more elementary channels can be surface channels, i.e., channels that do not pass through the layer. Such surface channels include grooves (whatever its shape), blind slot, blind recess, and so on.

The elementary channels are easy to make using conventional tooling techniques suitable to the material of the layers. Conventional tooling techniques include etching (e.g., using photo-lithography), engraving, drilling, laser, micro-fluidic technique, mechanical grinding, and so on.

FIG. 2B illustrates for example a top glass layer TL and a bottom glass layer BL, both in which a hole is performed using a laser, and an intermediary glass layer IL in which a straight through-opening slot is performed using micro-fluidic technology. The straight through-opening slot is made between the two positions collocated with the holes of the top and bottom glass layers. An alternative thereto may include performing a circular opening in the intermediary glass layer IL, which circular opening includes the two positions collocated with the holes of the top and bottom glass layers.

Next, at step 23, the multiple layers are assembled by stacking or lamination, using any adhering technology, including gluing, fusion bonding, cofiring, and so on.

This results in a layer stacking (on the right of FIG. 2B) where the holes and through-opening slot are aligned to form the continuous air vent 10. The inlet and outlet of the air vent 10 open in opposite faces of the resulting casing part.

For illustrative purposes, the manufacturing of a glass microfluidic part for two-phase flow may include the following steps: (1) a dry film resist is coated on a glass layer (e.g., IL); (2) UV are exposed through a properly-aligned mask to design a desired pattern; (3) developer solution (e.g., 0.2% NaCO3) is sprayed for fabrication of mask pattern; (4) micropowder is blasted using Al₂O₃ microparticles in order to etch the glass layer according to the pattern; (5) the mask is removed by remover solution (e.g., 3% NaOH); (6) the processed glass is cleaned and the multiple glass layers (TL, IL, BL) are aligned for bonding; and (7) performing fusion bonding to obtain the part.

For example, publication “Glass-to-Glass Fusion Bonding Quality and Strength Evaluation with Time, Applied Force, and Heat” (Nhi N. Trinh et al., 2022) describes a fusion bonding process.

The two or more layers (here glass layers) are first cleaned in a piranha solution (H₂SO₄:H₂O₂ = 4:1), then their surface (to be fused) is subjected to a two-stage plasma surface activation process, first with O₂ plasma at 75 W/100 W for 20 seconds (s) with a gas flow rate of 2500 sccm, then with N₂ MW radical activation at 75 W/150 W for 20 s with a gas flow rate of 5000 sccm. The layers are placed in a vacuum environment where they are heated to 450°C and then brought into direct contact with a 500 N load. Pressure is applied to achieve intimate contact between the surfaces to be fused, in order to form chemical bonds. This environment is held constant for several hours, before gradually returning to ambient temperature. The final fusion is then carried out, where the layers are held against each other under a pressure of around 500 to 1000 N, in an oven (500°C to 700°C) for 1 to 4 hours, before being allowed to cool gradually to room temperature. The result is a one-piece multi-layered part.

A result of steps 21 to 23 is the assembly of multiple layers having respective channels that form together a chicane-shaped air vent 10 coupling the cavity 9 with the outside. The obtained assembly forms one of the first and second casing parts 1a, 1b.

The other casing part may be formed in the same way (multilayer stacking) without performing the elementary channels, unless air vents are provided in the two casing parts of package 1.

Next, at step 24, one or more dies/chips 2 are formed and/or mounted on the bottom casing part 1b, which can be the casing part obtained through steps 21 to 23 in the case of FIG. 1B for example, or be another casing part (e.g., the bottom part) in the case of FIG. 1A. Chips 2 are for instance mounted on the bottom surface in the recess of the U-shape bottom frame 1b or simply mounted on a semiconductor substrate forming bottom frame. Conventional mounting techniques can be used.

Next, at step 25, the two casing parts (cover 1a and bottom frame 1b) are assembled together to obtain a casing defining the cavity 9 in which the chip or chips 2 are provided. The cover 1a may be adhered to the bottom frame 1b using conventional polymer glue, such as an epoxy glue.

FIG. 3A illustrates, through cross-section views, the manufacturing of a casing part having a chicane-shaped air vent 10 according to embodiments. This Figure corresponds to the manufacturing process of FIG. 2B with another positioning of the chicane-shaped air vent 10.

In this air vent 10, the outlet 12b opens in an outer surface of the casing part, e.g., in the top surface of the casing in FIG. 1A or in the bottom surface (used to connection with a PCB) of the casing in FIG. 1B. Also, the inlet 12a opens in an inner surface of the casing part, hence inside the cavity 9.

FIG. 3B illustrates, through cross-section views, the manufacturing of a casing part having a chicane-shaped air vent 10 according to embodiments.

The casing part is still manufactured by stacking three layers TL, IL, BL. The top layer TL includes two (or more) holes aligned with an opening in the intermediary layer IL, so that the chicane-shaped air vent 10 includes two (or more) outlets 12b to the outside, opening in an outer surface (here top surface) of the casing part.

In the casing part of the Figure, air vent 10 includes a single inlet 12a. Of course, multiple holes in the bottom layer BL aligned with the same opening of the intermediary layer IL may provide multiple inlets 12a opening in cavity 9. Alternatively, two (or more) inlets 12a may be provided with a single outlet 12b.

FIG. 3C illustrates, through cross-section views, the manufacturing of a casing part having a chicane-shaped air vent 10 according to embodiments.

The casing part is manufactured by stacking two layers TL, BL. The bottom layer BL includes a hole that defines the inlet opening in cavity 9. The top layer TL includes a straight (blind) groove – as surface channel – extending from a position collocated with the hole in the BL, to an edge of the top layer TL.

As shown in the bottom Figure, the result of the layer stacking is a chicane-shaped air vent 10 with only one chicane, and with an outlet 12b that opens in a side (or lateral) face of the casing.

The designs of FIGS. 3A, FIG. 3B and FIG. 3C, can be combined. For example, multiple outlets may be provided that open in the side face of the casing or different outlets of the same air vent 10 may be provided that open in different faces of the same casing part.

In those Figures, a single layer is shown as TL, IL or BL whereas each of TL, IL and BL may result from a stacking of multiple layers having the same aligned opening.

Also, only a two-chicane or single-chicane air vent is shown in these Figures, whereas more complex air vents (with more chicanes) can be obtained by adding further layers in the stacking.

FIG. 4 illustrates embodiments where the chicane-shaped air vent is located in a glass cover of the casing, facing a top and sensing surface of an image sensing chip.

FIG. 4 is a cross-section view of an optical sensor package, i.e., an integrated circuit (IC) package 1 with a TSV optical chip 2, manufactured using known techniques. TSV stands for “through-silicon via”. These TSV vias enable vertical connections to be made in the optical chip's stack of semiconductor layers, in particular connecting tracks formed on the chip's top surface to tracks formed on the chip's bottom surface. TSV vias contribute to chip compactness and integration, all at reduced cost.

An optical (image sensor) chip 2 is formed by a support substrate 3 forming a bottom frame of the package as illustrated, and having an upper (or inner) surface 3s for chip forming or mounting and a lower (or outer) surface 3i for connection to a printed circuit board PCB (not shown). Metal or connection pads 4 (of any form, such as lands, balls, bumps, cylinders, studs, pyramids, half-spheres) are attached to the lower surface 3i of the optical chip 2, which surface may include a signal redistribution layer 40. The connection pads 4 are designed to be soldered, for example, to the PCB (not shown). A matrix 5 (or array) of elementary sensors (or photoelectric cells) - typically photodiodes - is arranged on the top surface 3s of chip 2, to which micro-lenses 50 are attached. TSV connections 6 between matrix 5 and the connecting pads 4 offer enhanced miniaturization.

In order to produce color sensors, a color filter mask 51 can be placed in front of the array 5 of elementary sensors. This mask contains color filter areas placed at the same pitch as the elementary sensors, so that each elementary sensor has its own color filter in front of it. The color filters of neighboring elementary sensors are of a different primary color, for example red, green and blue. During image processing, the information from each of the groups of neighboring elementary sensors, usually four, can be combined into information for a single image pixel.

Spacers 7 are glued to the top surface 3s of the sensor chip 2 in an area outside the sensor matrix 5, typically around the perimeter of the top surface 3s, hence forming a ringframe of the casing. They are also attached, again using adhesive, to the lower surface of a glass plate 8, so as to hold it parallel to the optical chip 2 and at a small distance above it. The purpose of the glass cover plate 8 is to protect the surface of the sensor array 5 from damage, in particular from particles generated during the assembly process, while allowing light to reach the sensor array 5. The glass cover 8 includes a central or active portion 80 that is facing the sensing face of chip 2 for light reception or transmission and a surrounding portion 81 the bottom surface of which is mainly used for adhesion to spacers 7. The active portion 80 can correspond to the active cone of the chip 2, i.e., the cone of light directions the chip can emit or receive (sense).

Substrate 3, spacers 7 and glass cover 8 are casing parts that, once assembled (as shown in the Figure) form a casing with a cavity 9 in which chip 2 is located.

As illustrated, glass cover 8 includes a chicane-shaped air vent 10 to couple the cavity 9 with the outside, which chicane-shaped air vent is located in the surrounding portion 81 of the cover 8, not directly facing the top surface of the chip. This is to avoid interference between incoming light (to the sensor chip 2) and the air vent 10.

Glass cover 8 may be manufactured as described above with reference to FIGS. 1 - 3C. Indeed, although FIG. 4 shows a chicane-shaped air vent 10 of the type of FIG. 3A, any other type of air vent 10, such as those of FIGS. 3B or FIG. 3C or any other, can be used instead.

FIG. 5, similar to FIG. 1B, illustrates embodiments where the chicane-shaped air vent is located in the bottom frame of the casing, i.e., the frame having an outer surface that includes metal pads to connect the semiconductor package to a PCB. In these embodiments, the outlet 12b of the chicane-shaped air vent 10 opens in the bottom outer surface 3i of the casing.

The casing is made of ceramic. The sealing of the casing by gluing the cover 1a to the bottom frame 1b requires heating. The chicane-shaped air vent 10 helps the high pressured air in the cavity 9 resulting from the heating to be exhausted out. Afterwards, the chicane-shaped air vent 10 may no longer be needed, in particular in case the chip 2 does not produce too much heat.

The three figures at bottom of FIG. 5 are bottom views illustrating three finishing states for the outlet 12b (which may be multiple) according to embodiments. The three finishing states provide different levels of obstruction (or closure) of the chicane-shaped air vent 10.

It is recalled that thanks to the metal pads to connect the semiconductor package 1 to a PCB, the bottom surface 3i is slightly shifted from the top surface of the PCB, enabling air to circulate beneath the semiconductor package 1.

In embodiments as shown in the left Figure, the outlet 12b without any surrounding element (except the metal pads not shown) ensure the cavity 9 remains fully open to the external environment. The air flow that can enter the package cavity or be exhausted from the package cavity is maximum.

In embodiments as shown in the middle Figure, stoppers 120b, in the form of metalized lands, are provided in the surroundings of the outlet 12b. The metalized lands are disposed on the bottom surface 3i using known techniques, and are soldered to the PCB when the semiconductor package is attached thereto. As a result, the stoppers block a part of the air flow that can enter the package cavity or be exhausted from the package cavity. The cavity 9 is partially open to the external environment.

As shown in the Figure, the stoppers 120b may be formed by a discontinuous ring surrounding the outlet 12b. The number of discontinuities in the surrounding ring defines the number of stoppers 120b (four in the Figure; any other number may be contemplated). The width of the discontinuities (space between two stoppers) may be adjusted to the maximum air flow desired. The widths of multiple discontinuities may be the same or different ones.

In embodiments as shown in the right Figure, the outlet 12b is surrounded by a sealing element 121b, which may take the form of a metalized ring land. Once soldered to the PCB, the metalized ring land let no air flow to circulate through the outlet 12b, thereby sealing the chicane-shaped air vent 10 to the outside. The cavity 9 is close to the external environment.

Although the present disclosure has been described hereinabove with reference to specific embodiments, the present disclosure is not limited to the specific embodiments, and modifications will be apparent to a skilled person in the art which lie within the scope of the present disclosure.

1. A semiconductor package, comprising:
a casing defining a cavity and having a chicane-shaped air vent to couple the cavity with an outside, and
a chip in the cavity,
wherein the chicane-shaped air vent is formed by an assembly of straight channels performed each in a respective layer of a multilayer casing part.

2. The semiconductor package of claim 1, wherein a cross-section of the chicane-shaped air vent includes two or more straight channels disposed at a right angle.

3. The semiconductor package of claim 1, wherein the chicane-shaped air vent is located in a cover of the casing, facing a top surface of the chip.

4. The semiconductor package of claim 3, wherein the chicane-shaped air vent is located in a surrounding portion of the cover, not directly facing the top surface of the chip.

5. The semiconductor package of claim 1, wherein the chicane-shaped air vent is performed in a bottom frame of the casing, an outer surface of the bottom frame including metal pads to connect the semiconductor package to a circuit board.

6. The semiconductor package of claim 5, wherein an outlet of the chicane-shaped air vent in the outer surface of the bottom frame is surrounded by one or more stoppers arranged in a continuous or discontinuous surrounding pattern.

7. The semiconductor package of claim 6, wherein the bottom frame is a ceramic frame and the one or more stoppers.

8. The semiconductor package of claim 1, wherein an outlet of the chicane-shaped air vent opens in a top surface of the casing.

9. The semiconductor package of claim 1, wherein an outlet of the chicane-shaped air vent opens in a bottom surface of the casing used to mount the semiconductor package on a circuit board.

10. The semiconductor package of claim 1, wherein the chicane-shaped air vent includes a single inlet opening in the cavity and two or more outlets to the outside.

11. A method of manufacturing a semiconductor package, the method comprising:
providing a chip on a first casing part,
assembling the first casing part with a second casing part to obtain a casing defining a cavity in which the chip is provided,
wherein at least one of the first casing part and the second casing part is obtained by assembling multiple layers having respective straight channels that form together a chicane-shaped air vent coupling the cavity with an outside.

12. The method of manufacturing the semiconductor package of claim 11, wherein assembling multiple layers includes obtaining a top layer in which a hole is performed, an intermediary layer in which a straight through-opening slot or circular opening is performed, a bottom layer in which a hole is performed, and stacking using adhesion the top layer on the intermediary layer itself on the bottom layer in a way the hole of the top layer and the hole of the bottom layer are respectively aligned with the straight through-opening slot or circular opening of the intermediary layer.

13. The method of manufacturing the semiconductor package of claim 11, wherein assembling multiple layers includes a top layer comprising a straight groove and a bottom layer in which a hole is performed and stacking using adhesion the top layer on the bottom layer in a way the hole of the bottom layer is aligned with the straight groove of the top layer.

14. The method of manufacturing the semiconductor package of claim 12, wherein the top layer, the intermediary layer, and the bottom layer are glass layers.

15. The method of manufacturing the semiconductor package of claim 12, wherein the top layer, the intermediary layer, and the bottom layer are ceramic layers.
